(19) United States
(12) Patent Application Publication
(10) Pub. No.: US 2012/0032174 A1
(43) Pub. Date: Feb. 9, 2012

(54) SEMICONDUCTOR DEVICE, DISPLAY DEVICE AND ELECTRONIC DEVICE

(75) Inventor: Mao Katsuhara, Kanagawa (JP)

(73) Assignee: SONY CORPORATION, Tokyo (JP)

(21) Appl. No.: 13/192,954

(22) Filed: Jul. 28, 2011

(30) Foreign Application Priority Data
Aug. 6, 2010 (JP) 2010-177799

(51) Int. Cl. H01L 33/08; H01L 29/786

(52) U.S. Cl. 257/59; 257/57; 257/66; 257/72; 257/E33.012; 257/E29.273

(57) ABSTRACT

Disclosed herein is a semiconductor device including: a gate electrode on a substrate; a gate insulating film covering said gate electrode; an organic semiconductor layer disposed so as to be superposed above said gate electrode with said gate insulating film interposed between the organic semiconductor layer and the gate electrode within a width of said gate electrode; and a source electrode and a drain electrode having respective end parts disposed so as to be opposed to each other on said organic semiconductor layer in a state of said gate electrode being interposed between the source electrode and the drain electrode in a direction of the width of said gate electrode.

### BACKGROUND

The present disclosure relates to a semiconductor device, a display device, and an electronic device, and particularly to a semiconductor device of a thin film transistor constitution including an organic semiconductor layer, a display device including the semiconductor device, and an electronic device.

Semiconductor devices using an organic semiconductor layer as an active layer in which a channel region is formed, or so-called organic thin film transistors (organic TFTs), are classified into four types according to positional relation of a gate electrode, a source electrode, and a drain electrode to the organic semiconductor layer. A bottom gate structure having a gate electrode in a layer lower than an organic semiconductor layer, for example, includes two types, that is, a top contact structure in which a source electrode and a drain electrode are situated on the organic semiconductor layer and a bottom contact structure in which a source electrode and a drain electrode are situated under the organic semiconductor layer (see “Advanced Materials,” (2002), vol. 14, p. 99).

Of the structures, the top contact structure provides more secure contact between the source and drain electrodes and the organic semiconductor layer, and is a highly reliable electrode structure.

### SUMMARY

It is generally known that a channel region for charge conduction in an organic semiconductor layer serving as an active layer in a semiconductor device using the organic semiconductor layer is a very limited region of a layer from an interface with a gate insulating film to a few molecules (to 10 nm).

In the semiconductor device of the bottom gate and top contact structure described above, however, the source electrode and the drain electrode are in contact with an inactive region that does not become a channel region in the organic semiconductor layer. Thus, the inactive region of the organic semiconductor layer is interposed as a high resistance component between the source and drain electrodes and the channel region, and it is difficult to reduce contact resistance (injection resistance) with respect to the channel region.

While the resistance of the inactive region can be reduced by thinning the organic semiconductor layer, it is difficult to form a very thin film of up to about 10 nm uniformly in a large-area process. In addition, it is difficult to impart an excellent characteristic to the organic semiconductor layer in the region of such a very thin film, and the channel region in the organic semiconductor layer tends to be damaged in processes after the formation of the film.

It is accordingly desirable to provide a semiconductor device in which the contact resistance is reduced while the film quality of the organic semiconductor layer is ensured in the top contact structure providing secure contact between the source and drain electrodes and the organic semiconductor layer, and which semiconductor device is thereby improved in reliability and functionality. In addition, it is desirable to provide a display device and an electronic device improved in functionality by including such a semiconductor device.

According to an embodiment of the present disclosure, there is provided a semiconductor device including: a gate electrode on a substrate; a gate insulating film covering the gate electrode; an organic semiconductor layer disposed on the gate insulating film; and a source electrode and a drain electrode disposed on the organic semiconductor layer. The organic semiconductor layer is disposed so as to be superposed above the gate electrode with the gate insulating film interposed between the organic semiconductor layer and the gate electrode, and is disposed within a width of the gate electrode. In addition, respective end parts of the source electrode and the drain electrode are disposed so as to be opposed to each other on the organic semiconductor layer in a state of the gate electrode being interposed between the source electrode and the drain electrode in a direction of the width of the gate electrode.

The present technology is also a display device and an electronic device including the semiconductor device according to the above-described embodiment of the present disclosure.

In the semiconductor device of such a constitution, which is an organic thin film transistor of the bottom gate and top contact structure, there is secure contact between the source and drain electrodes and the organic semiconductor layer. In addition, in particular, the organic semiconductor layer is disposed within the range in the direction of width of the gate electrode. Therefore, in the part of the organic semiconductor layer interposed between the source electrode and the drain electrode, an entire surface between the source electrode and the drain electrode which surface is located in a boundary part between the organic semiconductor layer and the gate insulating film forms a channel region. Thus, the channel region is in direct contact with the source electrode and the drain electrode. Thereby, resistance components between the channel region and the source and drain electrodes can be eliminated without depending on the film thickness of the organic semiconductor layer.

As described above, according to the present technology, the resistance components between the channel region and the source and drain electrodes can be eliminated without depending on the film thickness of the organic semiconductor layer even in the case of the bottom gate and top contact structure. It is therefore possible to reduce contact resistance (injection resistance) with respect to the channel region while ensuring the film quality of the organic semiconductor layer, and improve the reliability and functionality of the organic semiconductor device. It is also possible to improve the reliability and functionality of a display device and an electronic device formed using a semiconductor device of such a constitution.

### BRIEF DESCRIPTION OF THE DRAWINGS

FIG. 1 is a sectional view and a plan view of a constitution of a semiconductor device according to a first embodiment;

FIGS. 2A to 2E are sectional process views of a first method of manufacturing the semiconductor device according to the first embodiment;

FIGS. 3A to 3E are sectional process views of a second method of manufacturing the semiconductor device according to the first embodiment;

FIG. 4 is a sectional view and a plan view of a constitution of a semiconductor device according to a second embodiment;

FIGS. 5A to 5E are sectional process views of an example of a method of manufacturing the semiconductor device according to the second embodiment;

FIG. 6 is a sectional view and a plan view of a constitution of a semiconductor device according to a third embodiment;

FIGS. 7A to 7E are sectional process views of an example of a method of manufacturing the semiconductor device according to the third embodiment;

FIG. 8 is a sectional view of an example of a display device according to a fourth embodiment;

FIG. 9 is a diagram of a circuit configuration of the display device according to the fourth embodiment;

FIG. 10 is a perspective view of a television set using a display device according to an embodiment of the present technology;

FIGS. 11A and 11B are perspective views of a digital camera using a display device according to an embodiment of the present technology, FIG. 11A being a perspective view of the digital camera as viewed from a front side, and FIG. 11B being a perspective view of the digital camera as viewed from a back side;

FIG. 12 is a perspective view of a notebook personal computer using a display device according to an embodiment of the present technology;

FIG. 13 is a perspective view of a video camera using a display device according to an embodiment of the present technology; and

FIGS. 14A, 14B, 14C, 14D, 14E, 14F, and 14G are external views of a portable terminal device, for example a portable telephone using a display device according to an embodiment of the present technology, FIG. 14A being a front view of the portable telephone in an opened state, FIG. 14B being a side view of the portable telephone in the opened state, FIG. 14C being a front view of the portable telephone in a closed state, FIG. 14D being a left side view of the portable telephone in the closed state, FIG. 14E being a right side view of the portable telephone in the closed state, FIG. 14F being a top view of the portable telephone in the closed state, and FIG. 14G being a bottom view of the portable telephone in the closed state.

### DETAILED DESCRIPTION OF THE PREFERRED EMBODIMENTS

Preferred embodiments of the present disclosure will hereinafter be described in the following order with reference to the drawings.

1. First Embodiment (Example of Embodiment of Semiconductor Device)

2. Second Embodiment (Example of Embodiment of Semiconductor Device Having Protective Film)

3. Third Embodiment (Example of Embodiment of Semiconductor Device in which Organic Semiconductor Layer Has Stepped Shape)

4. Fourth Embodiment (Example of Application to Display Device Using Thin Film Transistor)

5. Fifth Embodiment (Example of Application to Electronic Devices)

Incidentally, the same constituent elements in the first to third embodiments are identified by the same reference numerals, and repeated description thereof will be omitted.

### 1. First Embodiment

### <Constitution of Semiconductor Device>

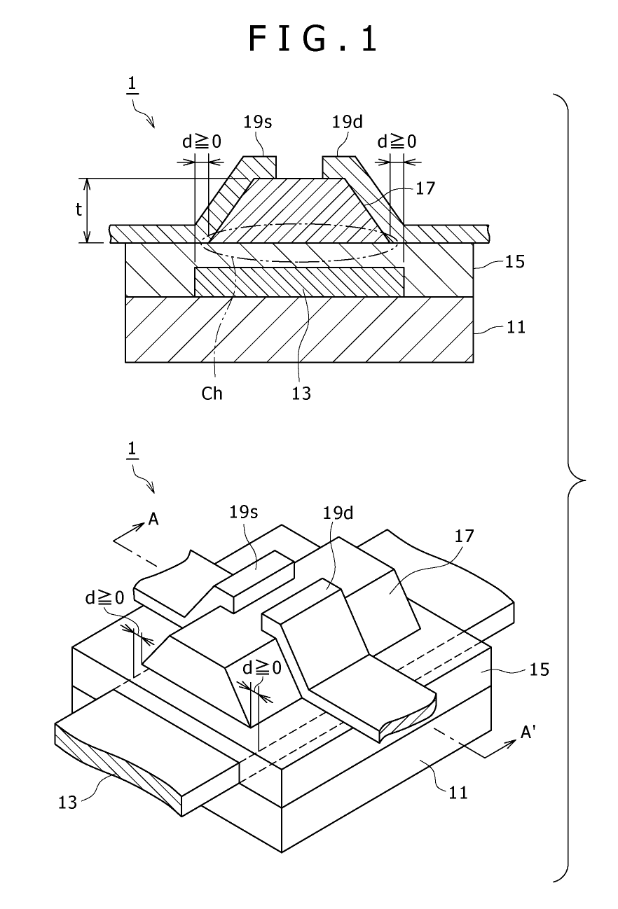

FIG. 1 is a sectional view and a plan view of a semiconductor device 1 according to a first embodiment. The sectional view corresponds to a section taken along a line A-A′ of the plan view. The semiconductor device 1 shown in these figures is a thin film transistor of a bottom gate and top contact structure. A gate insulating film 15 is provided on a substrate 11 in a state of covering a gate electrode 13 extended in one direction. An organic semiconductor layer 17 is provided on the gate insulating film 15. The organic semiconductor layer 17 is patterned in the shape of an island above the gate electrode 13, and is provided in a state of being laminated on the gate electrode 13 with the gate insulating film 15 interposed between the organic semiconductor layer 17 and the gate electrode 13. In addition, a source electrode 19s and a drain electrode 19d are provided on the gate insulating film 15 in such positions as to be opposed to each other with the gate electrode 13 interposed between the source electrode 19s and the drain electrode 19d. Suppose that edge parts of the source electrode 19s and the drain electrode 19d which edge parts are disposed so as to be opposed to each other with the gate electrode 13 interposed between the source electrode 19s and the drain electrode 19d are superposed on the organic semiconductor layer 17.

In the above constitution, according to the present first embodiment, the organic semiconductor layer 17 is disposed so as to be superposed above an upper part of the gate electrode 13 within a width of the gate electrode 13. That is, when the semiconductor device 1 is viewed in a plan view from the side of the source electrode 19s and the drain electrode 19d, both edges of the organic semiconductor layer 17 in a direction of the width of the gate electrode 13 coincide with the edges of the gate electrode 13, or are located on the inside of the edges of the gate electrode 13. It suffices for a plane interval d between the edges of the gate electrode 13 and the edges of the organic semiconductor layer 17 to be d≧0.

In addition, the organic semiconductor layer 17 desirably has a sectional shape such that film thickness of both edges of the organic semiconductor layer 17 in the direction of the width of the gate electrode 13 is smaller than film thickness t of a central part of the organic semiconductor layer 17 in the width direction. In this case, suppose that the central part having the film thickness t in the organic semiconductor layer 17 is at least a part sandwiched between the source electrode 19s and the drain electrode 19d, and is a part exposed from the source electrode 19s and the drain electrode 19d. Suppose that the film thickness t of the central part of such an organic semiconductor layer 17 is a sufficient thickness to prevent an interface between the organic semiconductor layer 17 and the gate insulating film 15, that is, a channel region from being damaged in a process of forming an even higher layer of the semiconductor device 1. Such a film thickness t is for example 30 nm or more, and is preferably 50 nm or more, though depending on a material forming the organic semiconductor layer 17.

Suppose that side walls of the organic semiconductor layer 17 of the above-described shape which side walls are on both sides in the direction of the width of the gate electrode 13 are formed in a tapered shape, for example. In the case of the tapered shape, an angle formed between the side walls of the tapered shape and the surface of the gate insulating film 15 is not limited as long as the film thickness t of the central part of the organic semiconductor layer 17 is a necessary film thickness.

Incidentally, it suffices for the organic semiconductor layer 17 to have the above-described sectional shape in a part having the source electrode 19s and the drain electrode 19d laminated thereon and a part sandwiched between the source electrode 19s and the drain electrode 19d. Thus, a part of the organic semiconductor layer 17 which part is on the side of the source electrode 19s and the drain electrode 19d may be formed so as to be wider than the gate electrode 13.

In addition, it suffices for the source electrode 19s and the drain electrode 19d to be at least laminated on the edges of the organic semiconductor layer 17 in the direction of the width of the gate electrode 13, and the source electrode 19s and the drain electrode 19d do not need to be superposed on as far as the central part (part of the film thickness t) of the organic semiconductor layer 17. Widths over which the source electrode 19s and the drain electrode 19d are superposed on the organic semiconductor layer 17 are desirably small from a viewpoint of reducing parasitic capacitances between the gate electrode 13 and the source electrode 19s and the drain electrode 19d.

Details of materials forming each of the above members will be described below in order from the lowest layer.

### <Substrate 11>

It suffices for at least the surface of the substrate 11 to be kept insulative. Not only a glass substrate but also a plastic substrate, a metallic foil substrate, paper or the like can be used as the substrate 11. Examples of the plastic substrate include polyethersulfone, polycarbonate, polyimides, polyamides, polyacetals, polyethylene terephthalate, polyethylene naphthalate, polyethyletherketone, and polyolefins. A substrate formed by laminating an insulative resin to a metallic foil made of aluminum, nickel, stainless steel or the like is used as the metallic foil substrate. In addition, functional films such as a buffer layer for improving adhesion and flatness, a barrier film for improving a gas barrier property, and the like may be formed on these substrates. A plastic substrate or a substrate using a metallic foil is applied to obtain flexibility.

### <Gate Electrode 13>

Metallic materials or organometallic materials are used for the gate electrode 13. The metallic materials used for the gate electrode 13 include gold (Au), platinum (Pt), palladium (Pd), silver (Ag), tungsten (W), tantalum (Ta), molybdenum (Mo), aluminum (Al), chromium (Cr), titanium (Ti), copper (Cu), nickel (Ni), indium (In), tin (Sn), manganese (Mn), ruthenium (Ru), and rubidium (Rb). These metallic materials are used as a simple substance or a compound. The organometallic materials used for the gate electrode 13 include (3,4-ethylenedioxythiophene)/poly(4-styrenesulfonate) [PEDOT/PSS], tetrathiafulvalene/tetracyanoquinodimethane [TTF/TCNQ], and the like. The formation of a material film forming the gate electrode 13 as described above can be performed by not only a vacuum deposition method such as a resistive heating deposition method, sputtering or the like but also a coating method as mentioned above using an ink paste. The film formation may also be performed by a plating method such as electroplating, electroless plating or the like.

### <Gate Insulating Film 15>

An inorganic insulating film or an organic insulating film can be used as the gate insulating film 15. Silicon oxide, silicon nitride, aluminum oxide, titanium oxide, hafnium oxide, or the like is used as an inorganic insulating film. A vacuum process such as a sputtering method, a resistive heating deposition method, a physical vapor deposition method (PVD), a chemical vapor deposition method (CVD) or the like is applied to the formation of these inorganic insulating films. Further, a sol-gel process for a solution in which a raw material is dissolved may be applied to the formation of these inorganic insulating films. On the other hand, for example a polymeric material such as polyvinyl phenol, a polyimide resin, a novolac resin, a cinnamate resin, an acrylic resin, an epoxy resin, a styrene resin, polyparaxylylene or the like can be used as an organic insulating film. A coating method or a vacuum process is applied to the formation of these organic insulating films. Examples of the coating method include a spin coating method, an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, a calender coater method, and a dipping method. Examples of the vacuum process include a chemical vapor deposition method and a vapor deposition polymerization method.

### <Organic Semiconductor Layer 17>

Examples of a material forming the organic semiconductor layer 17 include the following materials:

polypyrrole and polypyrrole substitution products,

polythiophene and polythiophene substitution products,

isothianaphthenes such as polyisothianaphthene and the like,

thienylenevinylenes such as polythienylenevinylene and the like,

poly(p-phenylenevinylenes) such as poly(p-phenylenevinylene) and the like

polyaniline and polyaniline substitution products,

polyacetylenes,

polydiacetylenes,

polyazulenes,

polypyrenes,

polycarbazoles,

polyselenophenes,

polyfurans,

poly(p-phenylenes),

polyindoles,

polypyridazines,

polymers such as polyvinyl carbazole, polyphenylene sulfide, polyvinylene sulfide and the like, and polycyclic condensation products,

oligomers having the same repetition units as those of polymers in the above-described materials,

acenes such as naphthacene, pentacene, hexacene, heptacene, dibenzopentacene, tetrabenzopentacene, pyrene, dibenzopyrene, chrysene, perylene, coronene, terylene, ovalene, quaterrylene, circumanthracene, and the like, derivatives in which atoms such as N, S, O, and the like or functional groups such as a carbonyl group and the like are substituted for a part of carbon of acenes (for example triphenodioxazine, triphenodithiazine, hexacene-6,15-quinone, perixanthenoxanthene and the like), and derivatives in which another functional group is substituted for hydrogen of the above derivatives,

metal phthalocyanines,

tetrathiafulvalene and tetrathiafulvalene derivatives,

tetrathiapentalene and tetrathiapentalene derivatives,

naphthalene-1,4,5,8-tetracarboxylic acid diimide, N,N′-bis(4-trifluoromethylbenzyl)naphthalene-1,4,5,8-tetracarboxylic acid diimide, N,N′-bis(1H,1H-perfluorooctyl), N,N′-bis(1H,1H-perfluorobutyl), N,N′-dioctylnaphthalene-1,4,5,8-tetracarboxylic acid diimide derivatives, and naphthalene tetracarboxylic acid diimides such as naphthalene-2,3,6,7-tetracarboxylic acid diimide and the like,

condensed ring tetracarboxylic acid diimides of anthracene tetracarboxylic acid diimides such as anthracene-2,3,6,7-tetracarboxylic acid diimide and the like,

fullerenes such as C60, C70, C76, C78, C84 and the like, and derivatives of these fullerenes,

carbon nanotubes such as SWNT and the like, and

dyes such as merocyanine dyes, hemicyanine dyes and the like, and derivatives of these dyes.

A coating method or a vacuum process is applied to the formation of film made of organic semiconductor materials as described above. Examples of the coating method include a spin coating method, an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, a calender coater method, and a dipping method. Examples of the vacuum process include a vapor deposition method such as resistive heating deposition, sputtering or the like.

<Source Electrode 19s/Drain Electrode 19d>

The source electrode 19s and the drain electrode 19d are formed by using a similar material to that of the gate electrode 13. It suffices for the material to be in ohmic contact with the organic semiconductor layer 17 in particular.

### <Manufacturing Method (1)>

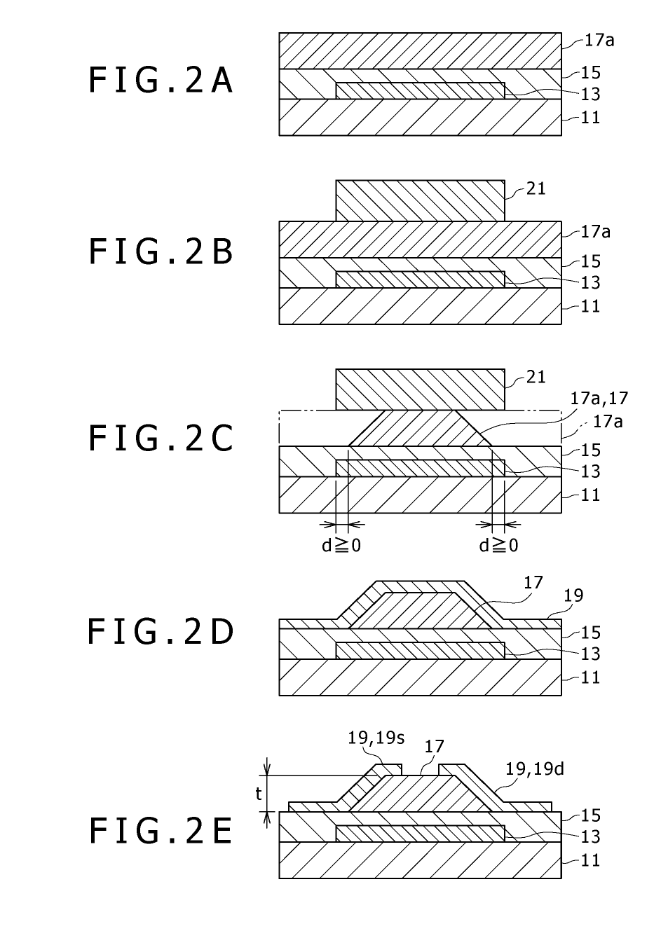

A method of forming a resist pattern directly on an organic semiconductor material film will be described as a first example of a method of manufacturing the semiconductor device 1 according to the first embodiment with reference to a sectional process view of FIGS. 2A to 2E.

First, as shown in FIG. 2A, a gate electrode 13 is pattern-formed on a substrate 11. In this case, after an electrode material film forming the gate electrode 13 described above is formed, a resist pattern (not shown) is formed on the electrode material film by applying a photolithography method, and the electrode material film is pattern-etched with the resist pattern as a mask, whereby the gate electrode 13 is obtained. The resist pattern is removed after completion of the etching.

Next, a gate insulating film 15 is formed on the entire surface of the substrate 11 in a state of covering the gate electrode 13. In this case, for example, the gate insulating film 15 made of polyvinyl phenol (PVP) is formed by coating by a spin coating method.

Next, an organic semiconductor material layer 17a is formed on the gate insulating film 15. In this case, the organic semiconductor material layer 17a is formed by using an organic semiconductor material having high resistance to an organic solvent. Accordingly, for example, the organic semiconductor material layer 17a made of poly(3-hexylthiophene) (P3HT) is formed with a film thickness of 50 nm by a spin coating method.

Thereafter, as shown in FIG. 2B, a photolithography method is applied to form a resist pattern 21 on the organic semiconductor material layer 17a. Suppose that the resist pattern 21 has substantially the same width as the width of the gate electrode 13, and is formed in a device region. Incidentally, a resist material made of a fluorine-base resin is desirably used for the resist pattern 21 formed in this case. It is thereby possible to prevent damage to the organic semiconductor material layer 17a, and perform a developing process that dissolves and removes the resist material selectively with respect to the organic semiconductor material layer 17a.

In the photolithography method for forming the resist pattern 21 of such a shape, backside exposure that applies exposure light from the side of the substrate 11 with the gate electrode 13 as a mask may be performed as an example. In this case, a positive-type resist material is used as the resist material. By such backside exposure, the resist pattern 21 of the same shape as the gate electrode 13 can be obtained in a position where the resist pattern 21 perfectly coincides with the gate electrode 13. Incidentally, when device isolation is necessary, it suffices to perform additional exposure from a surface side so as to pattern the resist pattern 21 in the extending direction of the gate electrode 13.

Next, as shown in FIG. 2C, the organic semiconductor material layer 17a is pattern-etched by etching using the resist pattern 21 as a mask, and thereby an organic semiconductor layer 17 is formed in such a position as to be superposed above the gate electrode 13. In this case, the side walls of the organic semiconductor layer 17 are formed into a forward tapered shape by performing isotropic etching. In addition, it is important that etching be allowed to progress sufficiently to such an extent that the organic semiconductor layer 17 is contained within the width of the gate electrode 13, and that the plane interval d between the edges in the width direction of the gate electrode 13 and the edges of the organic semiconductor layer 17 be d≧0.

Such etching of the organic semiconductor material layer 17a is performed by isotropic dry etching. An example of such dry etching is a reactive ion etching method using oxygen as an etching gas, for example. After completion of the etching, the resist pattern 21 is dissolved and removed selectively with respect to the organic semiconductor layer 17.

Next, as shown in FIG. 2D, an electrode material film 19 is formed on the gate insulating film 15 in a state of covering the organic semiconductor layer 17. In this case, a material brought into excellent ohmic contact with the organic semiconductor layer 17 is selected from the above-described materials, and formed by a vacuum deposition method, for example.

Next, as shown in FIG. 2E, a source electrode 19s and a drain electrode 19d are formed by patterning the electrode material film 19. In this case, a resist pattern (not shown) is formed on the electrode material film 19 by applying a photolithography method, and the electrode material film is pattern-etched with the resist pattern as a mask, whereby the source electrode 19s and the drain electrode 19d are obtained. It is important in this case to perform pattern etching such that end parts of the source electrode 19s and the drain electrode 19d are laminated on at least the edges of the organic semiconductor layer 17 in the direction of width of the gate electrode 13, and such that these end parts are disposed so as to be opposed to each other on the organic semiconductor layer 17. At this time, the end parts of the source electrode 19s and the drain electrode 19d do not need to be formed so as to be superposed on as far as the central part (part of the film thickness t) of the organic semiconductor layer 17. In this case, by using a water-soluble etchant, the electrode material film 19 is pattern-etched without affecting the organic semiconductor layer 17. The resist pattern is removed after completion of the pattern etching.

Thus, the semiconductor device 1 of a thin film transistor constitution of the bottom gate and top contact structure described with reference to FIG. 1 can be obtained.

### <Manufacturing Method (2)>

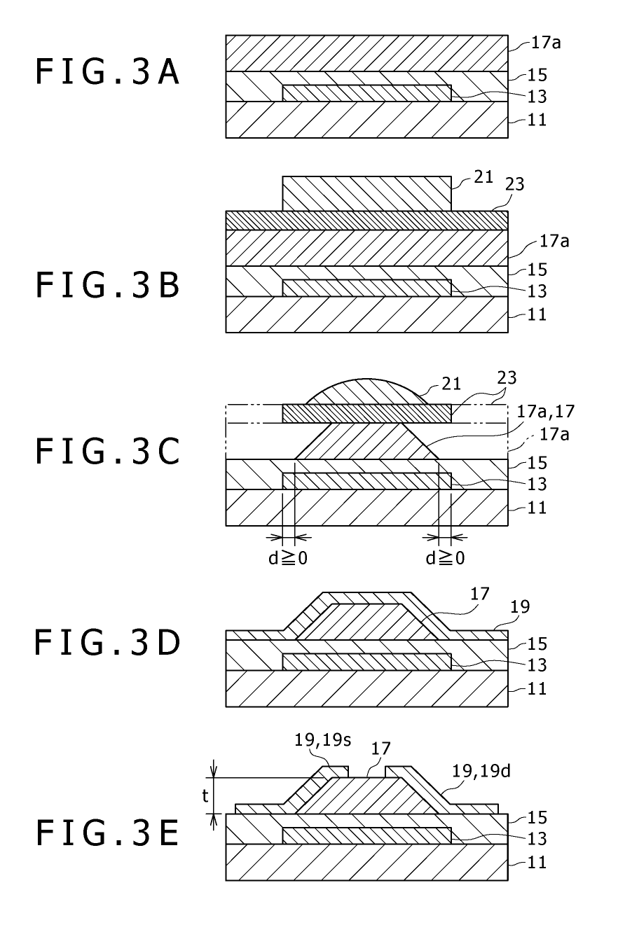

A method of forming a resist pattern on an organic semiconductor material film with a buffer layer interposed between the resist pattern and the organic semiconductor material film will be described as a second example of the method of manufacturing the semiconductor device 1 according to the first embodiment with reference to a sectional process view of FIGS. 3A to 3E.

First, as shown in FIG. 3A, a gate electrode 13 is formed on a substrate 11, a gate insulating film 15 made of PVP is formed in a state of covering the gate electrode 13, and an organic semiconductor material layer 17a is further formed on the gate insulating film 15. A process up to this point is performed in a similar manner to that described with reference to FIG. 2A in the foregoing first example.

However, an organic semiconductor material having high resistance to an organic solvent does not particularly need to be used for the organic semiconductor material layer 17a formed in this case. It suffices to use an organic semiconductor material providing a characteristic suitable for the semiconductor device formed in this case. Accordingly, the organic semiconductor material layer 17a made of pentacene is formed with a film thickness of 50 nm by a vacuum deposition method, for example.

Next, as shown in FIG. 3B, a metallic buffer layer 23 is formed on the organic semiconductor material layer 17a. The metallic buffer layer 23 is formed as a buffer layer for enabling etching to be performed without damaging the organic semiconductor material layer 17a. Such a metallic buffer layer 23 is for example made of gold, copper, aluminum or the like and is formed by a vacuum deposition method.

Next, a resist pattern 21 is formed on the metallic buffer layer 23 by applying a photolithography method. The resist pattern 21 has substantially the same width as the width of the gate electrode 13, and is formed in a device region, as in the first example.

However, because the resist pattern 21 formed in this case is formed on the metallic buffer layer 23, damage to the organic semiconductor material layer 17a does not need to be considered, and a resist material having an excellent patterning property can be used for the resist pattern 21 formed in this case.

Incidentally, when the metallic buffer layer 23 is so thin as to be able to transmit light, backside exposure that applies exposure light from the side of the substrate 11 with the gate electrode 13 as a mask may be performed in the photolithography method for forming the resist pattern 21 of such a shape. In this case, a positive-type resist material is used as the resist material. By such backside exposure, the resist pattern 21 of the same shape as the gate electrode 13 can be obtained in a position where the resist pattern 21 perfectly coincides with the gate electrode 13. Incidentally, when device isolation is necessary, it suffices to perform additional exposure from a surface side so as to pattern the resist pattern 21 in the extending direction of the gate electrode 13.

Next, as shown in FIG. 3C, the metallic buffer layer 23 is pattern-etched by etching using the resist pattern 21 as a mask. At this time, by performing wet etching using a water-soluble etchant, only the metallic buffer layer 23 is pattern-etched without the organic semiconductor material layer 17a being damaged.

Next, in a state of the resist pattern 21 being laminated, the organic semiconductor material layer 17a is pattern-etched with the metallic buffer layer 23 as a mask, and thereby an organic semiconductor layer 17 is formed in such a position as to be superposed above the gate electrode 13. In this case, as in the first example, the side walls of the organic semiconductor layer 17 are formed into a forward tapered shape by performing isotropic etching. In addition, it is important that etching be allowed to progress sufficiently to such an extent that the organic semiconductor layer 17 is contained within the width of the gate electrode 13, and that the plane interval d between the edges in the width direction of the gate electrode 13 and the edges of the organic semiconductor layer 17 be d≧0.

Such etching of the organic semiconductor material layer 17a is performed by isotropic dry etching as in the first example. That is, such etching of the organic semiconductor material layer 17a is performed by a reactive ion etching method using oxygen as an etching gas, for example. After completion of the etching, the metallic buffer layer 23 is removed by wet etching using a water-soluble etchant, and thereby the resist pattern 21 remaining on the metallic buffer layer 23 is also removed.

Thereafter, a source electrode and a drain electrode are formed as in FIG. 2D and FIG. 2E in the first example.

Specifically, first, as shown in FIG. 3D, an electrode material film 19 is formed on the gate insulating film 15 in a state of covering the organic semiconductor layer 17. In this case, a material brought into excellent ohmic contact with the organic semiconductor layer 17 is selected from the above-described materials, and formed by a vacuum deposition method, for example.

Next, as shown in FIG. 3E, a source electrode 19s and a drain electrode 19d are formed by patterning the electrode material film 19. In this case, a resist pattern (not shown) is formed on the electrode material film 19 by applying a photolithography method, and the electrode material film is pattern-etched with the resist pattern as a mask, whereby the source electrode 19s and the drain electrode 19d are obtained. It is important in this case to perform pattern etching such that end parts of the source electrode 19s and the drain electrode 19d are laminated on at least the edges of the organic semiconductor layer 17 in the direction of width of the gate electrode 13, and such that these end parts are disposed so as to be opposed to each other on the organic semiconductor layer 17. At this time, the end parts of the source electrode 19s and the drain electrode 19d do not need to be formed so as to be superposed on as far as the central part (part of the film thickness t) of the organic semiconductor layer 17. In this case, by using a water-soluble etchant, the electrode material film 19 is pattern-etched without affecting the organic semiconductor layer 17. The resist pattern is removed after completion of the pattern etching.

Thus, the semiconductor device 1 of a thin film transistor constitution of the bottom gate and top contact structure described with reference to FIG. 1 can be obtained.

Because the semiconductor device 1 of the above-described constitution is an organic thin film transistor of the bottom gate and top contact structure, there is secure contact between the source electrode 19s and the drain electrode 19d and the organic semiconductor layer 17. In addition, in particular, the organic semiconductor layer 17 is disposed within the range in the width direction of the gate electrode 13. Thus, in the part of the organic semiconductor layer 17 interposed between the source electrode 19s and the drain electrode 19d, an entire surface between the source electrode 19s and the drain electrode 19d which surface is located in a boundary part between the organic semiconductor layer 17 and the gate insulating film 15 forms a channel region ch. Thus, the source electrode 19s and the drain electrode 19d are in direct contact with the channel region ch. Thereby, resistance components between the channel region ch and the source electrode 19s and the drain electrode 19d can be eliminated without depending on the film thickness of the organic semiconductor layer 17.

In addition, both side walls of the organic semiconductor layer 17 in the direction of width of the gate electrode 13 have a tapered shape. It is therefore possible to reduce contact resistance (injection resistance) with respect to the channel region while suppressing parasitic capacitances between the channel region ch and the source electrode 19s and the drain electrode 19d.

Thus, it is possible to reduce the contact resistance (injection resistance) of the source electrode 19s and the drain electrode 19d with respect to the channel region ch while securing the film quality of the channel region ch by maintaining the film thickness of the organic semiconductor layer 17 at a certain magnitude. It is consequently possible to reduce the contact resistance and improve functionality without degrading reliability in the top contact structure that has been considered to provide secure contact between the source electrode and the drain electrode and the organic semiconductor layer but present a difficulty in reducing the contact resistance.

### 2. Second Embodiment

### <Constitution of Semiconductor Device>

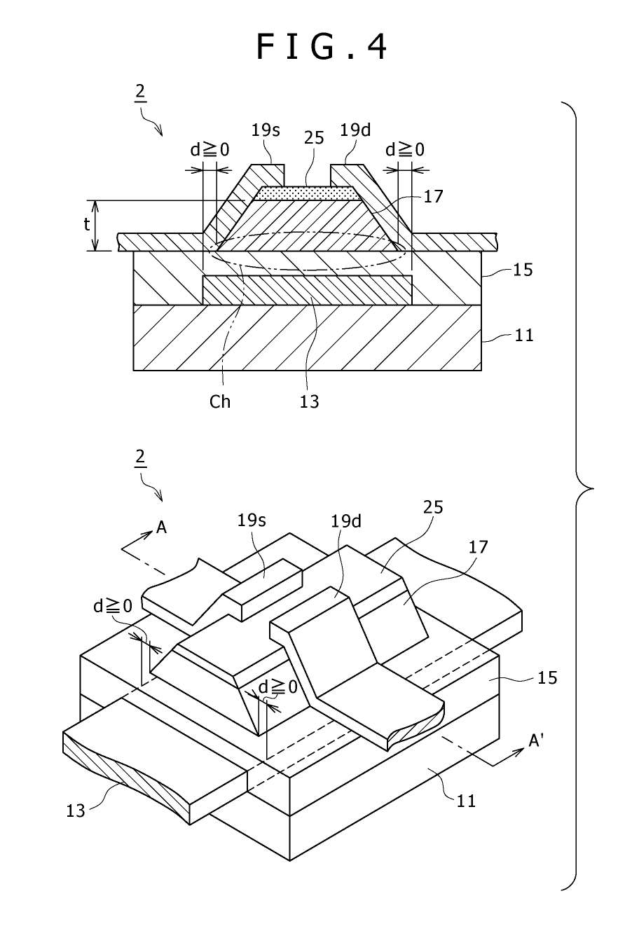

FIG. 4 is a sectional view and a plan view of a semiconductor device 2 according to a second embodiment. The sectional view corresponds to a section taken along a line A-A′ of the plan view. The semiconductor device 2 shown in these figures is a thin film transistor of a top contact and bottom gate structure as in the first embodiment. In the semiconductor device 2, an organic semiconductor layer 17 is disposed so as to be superposed above a gate electrode 13 with a gate insulating film 15 interposed between the organic semiconductor layer 17 and the gate electrode 13 within the width of the gate electrode 13, as in the first embodiment. The present second embodiment has a constitution including an insulating protective film 25 laminated on the upper part of the organic semiconductor layer 17. The other constitution and materials forming other respective parts are similar to those of the first embodiment.

Specifically, in the semiconductor device 2, the gate electrode 13 provided on a substrate 11 is covered by the gate insulating film 15, a laminate of the organic semiconductor layer 17 and the protective film 25 patterned in the shape of an island is provided on the upper part of the gate insulating film 15, and a source electrode 19s and a drain electrode 19d are provided.

The protective film 25 of the present second embodiment is a film for protecting the organic semiconductor layer 17 from damage when the organic semiconductor layer 17 is pattern-formed. Such a protective film 25 is formed of an organic insulating material or an inorganic insulating material. An organic insulating material, in particular, is preferable because an organic insulating material can be etched in a same process as an organic semiconductor material film forming the organic semiconductor layer 17 when the organic semiconductor layer 17 is pattern-formed. A fluorocarbon resin can be used as such an organic insulating material.

In addition, in the second embodiment, the organic semiconductor layer 17 having the above-described protective film 25 laminated thereon is disposed so as to be superposed above the gate electrode 13 within the width of the gate electrode 13, as in the first embodiment. That is, when the semiconductor device 2 is viewed in a plan view from the side of the source electrode 19s and the drain electrode 19d, both edges of the organic semiconductor layer 17 in a direction of the width of the gate electrode 13 coincide with edges of the gate electrode 13, or are located on the inside of the edges of the gate electrode 13. It suffices for a plane interval d between the edges of the gate electrode 13 and the edges of the organic semiconductor layer 17 to be d≧0.

In addition, the organic semiconductor layer 17 desirably has a sectional shape such that film thickness of both edges of the organic semiconductor layer 17 in the direction of the width of the gate electrode 13 is smaller than film thickness t of a central part of the organic semiconductor layer 17 in the width direction, as in the first embodiment. In this case, suppose that the central part of the organic semiconductor layer 17 which central part has the film thickness t is at least a part sandwiched between the source electrode 19s and the drain electrode 19d, and is a part exposed from the source electrode 19s and the drain electrode 19d.

However, in the present second embodiment, it suffices for the film thickness t of the central part of such an organic semiconductor layer 17 to be such that the organic semiconductor layer 17 is formed as a film having stable film quality, and consideration does not need to be given to damage caused by a process in forming higher layers. Such a film thickness t is for example 30 nm or more, and is preferably 50 nm or more, though depending on a material forming the organic semiconductor layer 17.

Suppose that side walls of the organic semiconductor layer 17 of the above-described shape in the direction of the width of the gate electrode 13 are formed in a tapered shape, as in the first embodiment. In the case of the tapered shape, an angle formed between the side walls of the tapered shape and the surface of the gate insulating film 15 is not limited as long as the film thickness t of the central part of the organic semiconductor layer 17 is a necessary film thickness.

Incidentally, as in the first embodiment, it suffices for the organic semiconductor layer 17 to have the above-described sectional shape in a part having the source electrode 19s and the drain electrode 19d laminated thereon and a part sandwiched between the source electrode 19s and the drain electrode 19d. Thus, a part of the organic semiconductor layer 17 which part is on the side of the source electrode 19s and the drain electrode 19d may be formed so as to be wider than the gate electrode 13.

In addition, as in the first embodiment, it suffices for the source electrode 19s and the drain electrode 19d to be at least laminated on the edges of the organic semiconductor layer 17 in the direction of the width of the gate electrode 13. Thus, the source electrode 19s and the drain electrode 19d do not need to be superposed on as far as the central part (part of the film thickness t) of the organic semiconductor layer 17, that is, the protective film 25. Widths over which the source electrode 19s and the drain electrode 19d are superposed on the organic semiconductor layer 17 are desirably small from a viewpoint of reducing parasitic capacitances between the gate electrode 13 and the source electrode 19s and the drain electrode 19d, as in the first embodiment.

### <Manufacturing Method>

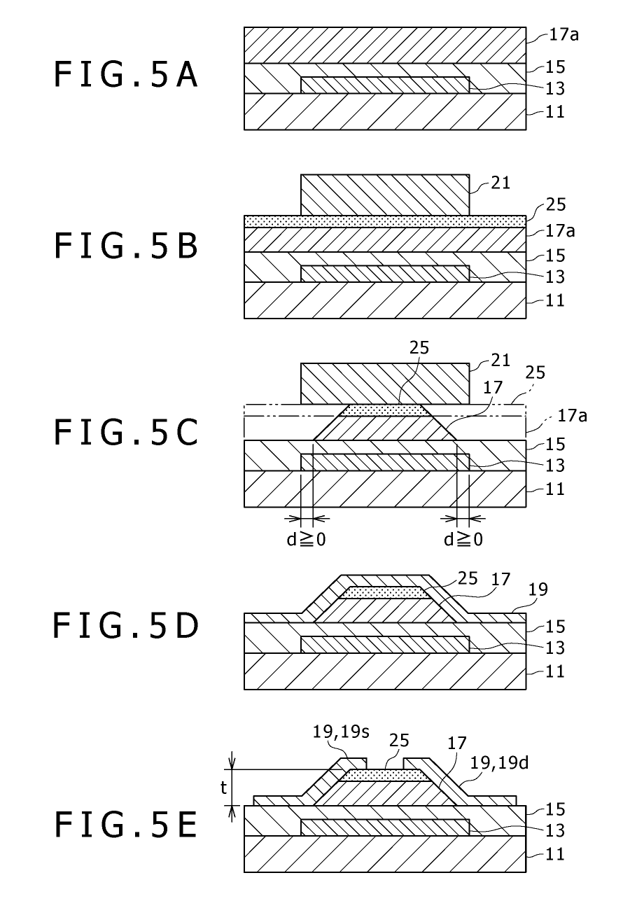

A method of manufacturing the semiconductor device 2 according to the second embodiment as described above will be described with reference to a sectional process view of FIGS. 5A to 5E.

First, as shown in FIG. 5A, a gate electrode 13 is formed on a substrate 11, a gate insulating film 15 made of PVP is formed in a state of covering the gate electrode 13, and an organic semiconductor material layer 17a is further formed on the gate insulating film 15. A process up to this point is performed in a similar manner to that described with reference to FIG. 2A in the first example of the method of manufacturing the semiconductor device according to the first embodiment.

However, an organic semiconductor material having high resistance to an organic solvent does not particularly need to be used for the organic semiconductor material layer 17a formed in this case. It suffices to use an organic semiconductor material providing a characteristic suitable for the semiconductor device formed in this case. Accordingly, the organic semiconductor material layer 17a made of pentacene is formed with a film thickness of 50 nm by a vacuum deposition method, for example.

Next, as shown in FIG. 5B, a protective film 25 is formed on the organic semiconductor material layer 17a. This protective film 25 is formed as a film for protecting the organic semiconductor material layer 17a. Such a protective film 25 is made of a fluorocarbon resin, for example, and is formed by coating by a spin coating method.

Next, a resist pattern 21 is formed on the protective film 25 by applying a photolithography method. The resist pattern 21 has substantially the same width as the width of the gate electrode 13, and is formed in a device region, as in the first example and the second example of the first embodiment.

However, because the resist pattern 21 formed in this case is formed on the protective film 25, damage to the organic semiconductor material layer 17a does not need to be considered, and a resist material having an excellent patterning property can be used for the resist pattern 21 formed in this case.

In addition, in the photolithography method for forming the resist pattern 21 of such a shape, backside exposure that applies exposure light from the side of the substrate 11 with the gate electrode 13 as a mask may be performed as an example, as in the first example. Thus, in this case, a positive-type resist material is used as the resist material. By such backside exposure, the resist pattern 21 of the same shape as the gate electrode 13 can be obtained in a position where the resist pattern 21 perfectly coincides with the gate electrode 13. Incidentally, when device isolation is necessary, it suffices to perform additional exposure from a surface side so as to pattern the resist pattern 21 in the extending direction of the gate electrode 13.

Next, as shown in FIG. 5C, the protective film 25 is pattern-etched, and the organic semiconductor material layer 17a is further pattern-etched, by etching using the resist pattern 21 as a mask. A laminate of an organic semiconductor layer 17 and the protective film 25 is formed in such a position as to be superposed above the gate electrode 13.

In this case, at least the organic semiconductor material layer 17a is etched by isotropic etching, as in the first example and the second example of the first embodiment. The side walls of the organic semiconductor layer 17 are thereby formed into a forward tapered shape. It is important that etching be allowed to progress sufficiently to such an extent that the organic semiconductor layer 17 is contained within the width of the gate electrode 13, and that the plane interval d between the edges in the width direction of the gate electrode 13 and the edges of the organic semiconductor layer 17 be d≧0.

At this time, in a case where the protective film 25 is formed of an organic material such as a fluorocarbon resin or the like, the pattern etching of the protective film 25 and the organic semiconductor material layer 17a is performed in a same process. Such etching of the protective film 25 and the organic semiconductor material layer 17a is performed by isotropic dry etching. That is, such etching of the protective film 25 and the organic semiconductor material layer 17a is performed by a reactive ion etching method using oxygen as an etching gas, for example. Incidentally, the pattern etching of the protective film 25 and the pattern etching of the organic semiconductor material layer 17a may be performed in respective separate processes. After completion of the etching, the remaining resist pattern 21 is dissolved and removed selectively with respect to the organic semiconductor layer 17 and the protective film 25.

Thereafter, a source electrode and a drain electrode are formed as in the first example and the second example of the first embodiment.

Specifically, first, as shown in FIG. 5D, an electrode material film 19 is formed on the gate insulating film 15 in a state of covering the protective film 25 and the organic semiconductor layer 17 that have been patterned. In this case, a material brought into excellent ohmic contact with the organic semiconductor layer 17 is selected from the above-described materials, and formed by a vacuum deposition method, for example.

Next, as shown in FIG. 5E, a source electrode 19s and a drain electrode 19d are formed by patterning the electrode material film 19. In this case, a resist pattern (not shown) is formed on the electrode material film 19 by applying a photolithography method, and the electrode material film is pattern-etched with the resist pattern as a mask, whereby the source electrode 19s and the drain electrode 19d are obtained. It is important in this case to perform pattern etching such that end parts of the source electrode 19s and the drain electrode 19d are laminated on at least the edges of the organic semiconductor layer 17 in the direction of width of the gate electrode 13, and such that these end parts are disposed so as to be opposed to each other above the organic semiconductor layer 17. At this time, the end parts of the source electrode 19s and the drain electrode 19d do not need to be formed so as to be superposed on as far as the central part (part of the film thickness t) of the organic semiconductor layer 17, that is, the protective film 25. The resist pattern is removed after completion of the pattern etching.

Thus, the semiconductor device 2 of a thin film transistor constitution of the bottom gate and top contact structure described with reference to FIG. 4 can be obtained.

Because the semiconductor device 2 of the above-described constitution is an organic thin film transistor of the bottom gate and top contact structure, there is secure contact between the source electrode 19s and the drain electrode 19d and the organic semiconductor layer 17. In addition, as in the first embodiment, the organic semiconductor layer 17 is disposed within the range in the width direction of the gate electrode 13. Thus, as in the semiconductor device according to the first embodiment, in the part of the organic semiconductor layer 17 interposed between the source electrode 19s and the drain electrode 19d, an entire surface between the source electrode 19s and the drain electrode 19d which surface is located in a boundary part between the organic semiconductor layer 17 and the gate insulating film 15 forms a channel region ch. Thus, the source electrode 19s and the drain electrode 19d are in direct contact with the channel region ch. Thereby, resistance components between the channel region ch and the source electrode 19s and the drain electrode 19d can be eliminated without depending on the film thickness of the organic semiconductor layer 17.

In addition, as in the first embodiment, both side walls of the organic semiconductor layer 17 in the direction of width of the gate electrode 13 have a tapered shape. It is therefore possible to reduce contact resistance (injection resistance) with respect to the channel region while suppressing parasitic capacitances between the channel region ch and the source electrode 19s and the drain electrode 19d.

In particular, the semiconductor device 2 according to the present second embodiment has a constitution in which the upper surface of the organic semiconductor layer 17 is covered by the protective film 25. Therefore the film quality of the channel region ch is ensured without the organic semiconductor layer 17 being damaged by a manufacturing process.

Thus, it is possible to reduce the contact resistance (injection resistance) of the source electrode 19s and the drain electrode 19d with respect to the channel region ch while securing the film quality of the channel region ch more reliably than in the constitution of the first embodiment. It is consequently possible to reduce the contact resistance and improve functionality without degrading reliability in the top contact structure that has been considered to provide secure contact between the source electrode and the drain electrode and the organic semiconductor layer but present a difficulty in reducing the contact resistance.

### Third Embodiment

### <Constitution of Semiconductor Device>

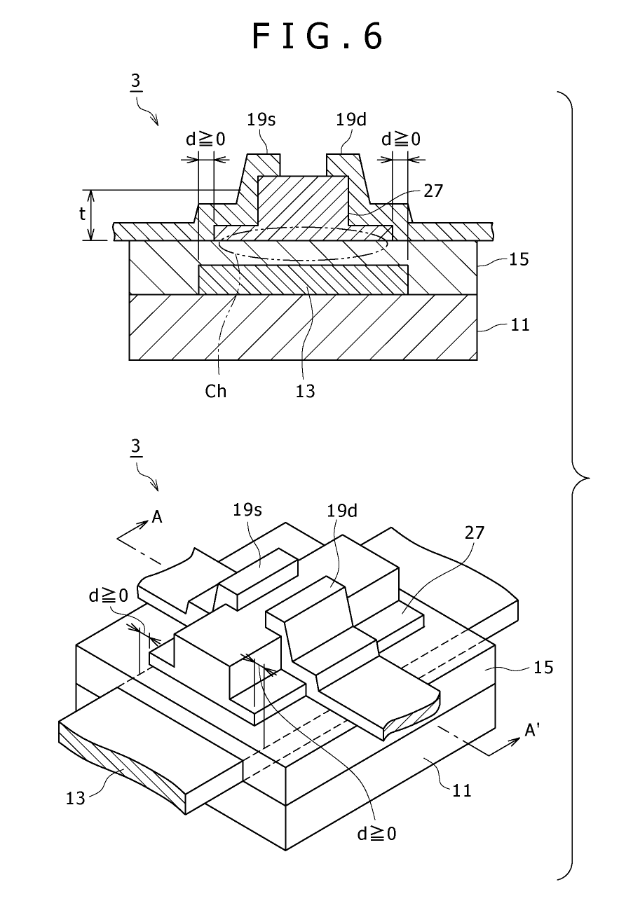

FIG. 6 is a sectional view and a plan view of a semiconductor device 3 according to a third embodiment. The sectional view corresponds to a section taken along a line A-A′ of the plan view. The semiconductor device 3 shown in these figures is a thin film transistor of a top contact and bottom gate structure as in the first embodiment and the second embodiment. In the semiconductor device 3, an organic semiconductor layer 27 is disposed so as to be superposed above a gate electrode 13 with a gate insulating film 15 interposed between the organic semiconductor layer 27 and the gate electrode 13 within the width of the gate electrode 13, as in the first embodiment and the second embodiment. In such a constitution, film thickness of both edges of the organic semiconductor layer 27 in the direction of width of the gate electrode 13 is reduced stepwise. The other constitution and materials forming other respective parts are similar to those of the first embodiment.

Specifically, in the semiconductor device 3 according to the third embodiment, as in the first embodiment, the gate electrode 13 on a substrate 11 is covered by the gate insulating film 15, the organic semiconductor layer 27 patterned in the shape of an island is provided on the gate insulating film 15, and a source electrode 19s and a drain electrode 19d are provided.

The organic semiconductor layer 27 has a sectional shape such that the film thickness of both edges of the organic semiconductor layer 27 in the direction of width of the gate electrode 13 is smaller than film thickness t of a central part of the organic semiconductor layer 27 in the width direction, and is reduced in film thickness stepwise toward both the edges. That is, both the edges are reduced in film thickness with a level difference with reference to the central part having the film thickness t. The present third embodiment illustrates a case where the film thickness of both the edges is reduced in one step as compared with the central part of the film thickness t.

In this case, suppose that the central part of the organic semiconductor layer 27 which central part has the film thickness t is at least a part sandwiched between the source electrode 19s and the drain electrode 19d, and is a part exposed from the source electrode 19s and the drain electrode 19d.

Suppose that the film thickness t of the central part of such an organic semiconductor layer 27 is a sufficient film thickness to prevent an interface between the organic semiconductor layer 27 and the gate insulating film 15, that is, a channel region from being damaged in a process of forming an even higher layer of the semiconductor device 3. Such a film thickness t is for example 30 nm or more, and is preferably 50 nm or more, though depending on a material forming the organic semiconductor layer 27. On the other hand, the film thickness of the edge parts thinned in the organic semiconductor layer 27 is desirably small in a range where the edge parts function as the organic semiconductor layer 27. Suppose that the film thickness of such thin film parts is for example about 10 nm, though depending on the material forming the organic semiconductor layer 27.

Both the edges of the organic semiconductor layer 27 of such a shape in the direction of width of the gate electrode 13 may be formed in a stair shape of a plurality of steps, and the number of steps is not limited. However, as the number of steps of the stair shape is increased, the organic semiconductor layer 27 more resembles the shape of the organic semiconductor layer 17 in the first embodiment. In addition, both the edge parts thinned with a level difference with respect to the central part of the organic semiconductor layer 27 which central part has the film thickness t may be in a forward tapered shape.

The organic semiconductor layer 27 having the sectional shape as described above is disposed so as to be superposed above the gate electrode 13 within the width of the gate electrode 13, as in the first embodiment. That is, when the semiconductor device 3 is viewed in a plan view from the side of the source electrode 19s and the drain electrode 19d, both edges of the organic semiconductor layer 27 in the direction of width of the gate electrode 13 coincide with the edges of the gate electrode 13, or are located on the inside of the edges of the gate electrode 13. It suffices for a plane interval d between the edges of the gate electrode 13 and the edges of the organic semiconductor layer 27 to be d≧0.

In addition, as in the first embodiment and the second embodiment, it suffices for the organic semiconductor layer 27 to have the above-described sectional shape in a part having the source electrode 19s and the drain electrode 19d laminated thereon and a part sandwiched between the source electrode 19s and the drain electrode 19d. Thus, a part of the organic semiconductor layer 27 which part is on the side of the source electrode 19s and the drain electrode 19d may be formed so as to be wider than the gate electrode 13.

In addition, it suffices for the source electrode 19s and the drain electrode 19d to be at least laminated on the thin film parts of the organic semiconductor layer 27 in the direction of the width of the gate electrode 13. Thus, the source electrode 19s and the drain electrode 19d do not need to be superposed on as far as the central part (part of the film thickness t) of the organic semiconductor layer 27. Widths over which the source electrode 19s and the drain electrode 19d are superposed on the organic semiconductor layer 27 are desirably small from a viewpoint of reducing parasitic capacitances between the gate electrode 13 and the source electrode 19s and the drain electrode 19d, as in the first embodiment.

### <Manufacturing Method>

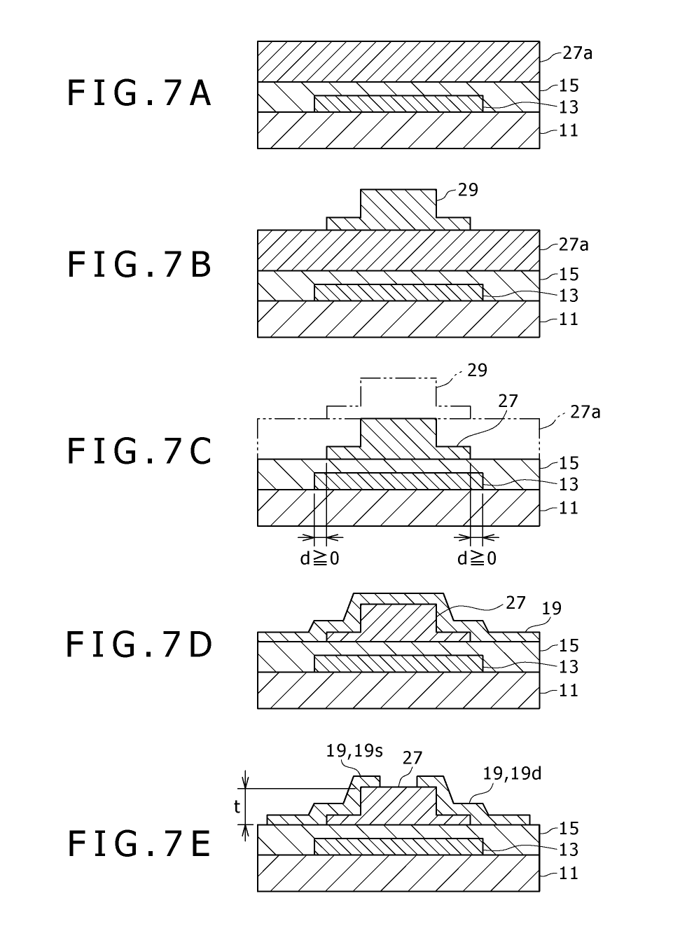

The semiconductor device 3 according to the third embodiment as described above can be manufactured by for example applying the first example of the manufacturing method according to the first embodiment and changing a photolithography process in forming a resist pattern for pattern-etching the organic semiconductor layer 27. Description in the following will be made with reference to a sectional process view of FIG. 7.

First, as shown in FIG. 7A, a gate electrode 13 is formed on a substrate 11, a gate insulating film 15 made of PVP is formed in a state of covering the gate electrode 13, and an organic semiconductor material layer 27a is further formed on the gate insulating film 15. A process up to this point is performed in a similar manner to that described with reference to FIG. 2A in the first example of the method of manufacturing the semiconductor device 1 described above. Specifically, the organic semiconductor material layer 27a is formed with a film thickness of 50 nm by a spin coating method using an organic semiconductor material having high resistance to an organic solvent such as poly(3-hexylthiophene) (P3HT) or the like.

Next, as shown in FIG. 7B, a resist pattern 29 is formed on the organic semiconductor material layer 27a by applying a photolithography method. In this case, the resist pattern is exposed to light by performing light exposure using a halftone mask or two-step light exposure such that an amount of light exposure of edges of the resist pattern in the direction of width of the gate electrode 13 is different from an amount of light exposure of a central part of the resist pattern in the direction of width of the gate electrode 13. The resist pattern 29 formed such that film thickness of both edges of the resist pattern 29 in the direction of width of the gate electrode 13 is smaller than that of the central part of the resist pattern 29 is thereby obtained. Suppose that the resist pattern 29 has substantially the same width as the width of the gate electrode 13, and is formed in a device region.

Incidentally, as in the first example of the first embodiment, a resist material made of a fluorine-base resin is desirably used for the resist pattern 29 formed in this case. A developing process that does not damage the organic semiconductor material layer 27a can be performed by using a similar developer to that of the first example of the first embodiment.

Next, as shown in FIG. 7C, the organic semiconductor material layer 27a is pattern-etched by etching from above the resist pattern 29, and thereby an organic semiconductor layer 27 is formed in such a position as to be superposed above the gate electrode 13. In this case, the shape of the resist pattern 29 is transferred to the organic semiconductor material layer 27a by performing anisotropic etching of the organic semiconductor material layer 27a together with the resist pattern 29. Thereby the organic semiconductor layer 27 is obtained which is disposed so as to be superposed above the gate electrode 13 within the width of the gate electrode 13 and which has a sectional shape such that the film thickness of both edges of the organic semiconductor layer 27 in the direction of width of the gate electrode 13 is smaller than the film thickness t of the central part of the organic semiconductor layer 27 in the width direction.

The anisotropic etching as described above is performed by a reactive ion etching method using oxygen as an etching gas, for example. When the resist pattern 29 remains after completion of the etching, the resist pattern 29 is dissolved and removed selectively with respect to the organic semiconductor layer 27. Incidentally, the resist pattern 29 remaining on only the central thick film part of the organic semiconductor layer 27 may be left as it is as a protective film without being removed.

Thereafter, a source electrode and a drain electrode are formed as in the first example of the first embodiment.

Specifically, first, as shown in FIG. 7D, an electrode material film 19 is formed on the gate insulating film 15 in a state of covering the organic semiconductor layer 27. In this case, a material brought into excellent ohmic contact with the organic semiconductor layer 27 is selected from the above-described materials, and formed by a vacuum deposition method, for example.

Next, as shown in FIG. 7E, a source electrode 19s and a drain electrode 19d are formed by patterning the electrode material film 19. In this case, a resist pattern (not shown) is formed on the electrode material film 19 by applying a photolithography method, and the electrode material film is pattern-etched with the resist pattern as a mask, whereby the source electrode 19s and the drain electrode 19d are obtained. It is important in this case to perform pattern etching such that end parts of the source electrode 19s and the drain electrode 19d are laminated on at least the edges of the organic semiconductor layer 27 in the direction of width of the gate electrode 13, and such that these end parts are disposed so as to be opposed to each other on the organic semiconductor layer 27. At this time, the end parts of the source electrode 19s and the drain electrode 19d do not need to be formed so as to be superposed on as far as the central part (part of the film thickness t) of the organic semiconductor layer 27. In this case, by using a water-soluble etchant, the electrode material film 19 is pattern-etched without affecting the organic semiconductor layer 27. The resist pattern is removed after completion of the pattern etching.

Thus, the semiconductor device 3 of a thin film transistor constitution of the bottom gate and top contact structure described with reference to FIG. 6 can be obtained.

Because the semiconductor device 3 of the above-described constitution is an organic thin film transistor of the bottom gate and top contact structure, there is secure contact between the source electrode 19s and the drain electrode 19d and the organic semiconductor layer 27. In addition, as in the other embodiments, the organic semiconductor layer 27 is disposed within the range in the width direction of the gate electrode 13. Thus, as in the other embodiments, in the part of the organic semiconductor layer 27 interposed between the source electrode 19s and the drain electrode 19d, an entire surface between the source electrode 19s and the drain electrode 19d which surface is located in a boundary part between the organic semiconductor layer 27 and the gate insulating film 15 forms a channel region ch. Thus, the source electrode 19s and the drain electrode 19d are in direct contact with the channel region ch. Thereby, resistance components between the channel region ch and the source electrode 19s and the drain electrode 19d can be eliminated without depending on the film thickness of the organic semiconductor layer 27.

In particular, in the semiconductor device 3 according to the present third embodiment, the edges of the organic semiconductor layer 27 in the direction of width of the gate electrode 13 are thinned with a level difference with respect to the central part of the organic semiconductor layer 27. It is therefore possible to reduce contact resistance (injection resistance) with respect to the channel region while suppressing parasitic capacitances between the channel region ch and the source electrode 19s and the drain electrode 19d.

Thus, it is possible to reduce the contact resistance of the source electrode 19s and the drain electrode 19d with respect to the channel region ch more reliably than in the constitutions of the other embodiments. It is consequently possible to reduce the contact resistance and improve functionality without degrading reliability in the top contact structure that has been considered to provide secure contact between the source electrode and the drain electrode and the organic semiconductor layer but present a difficulty in reducing the contact resistance.

Semiconductor devices according to embodiments of the present disclosure are not limited to the constitutions and the manufacturing methods illustrated in the first to third embodiments, but are susceptible of various modifications based on the technical ideas of the present disclosure, whereby similar effects can be obtained. For example, the formation of the resist pattern used as a mask at the time of etching is not limited to the application of photolithography technology, but the pattern may also be formed directly by a printing method. Examples of the printing method include ink-jet printing, screen printing, offset printing, gravure printing, flexographic printing, and microcontact printing. In addition, the third embodiment may be combined with the second embodiment to be provided with a protective film made of an insulating material on the central part of the film thickness t in the organic semiconductor layer 27.

### 4. Fourth Embodiment

Description will next be made of a constitution of a display device including a thin film transistor of a constitution described in an above-described embodiment. An active matrix type display device using an organic electroluminescent element EL will be described below as an example of the display device.

### <Layer Constitution of Display Device>

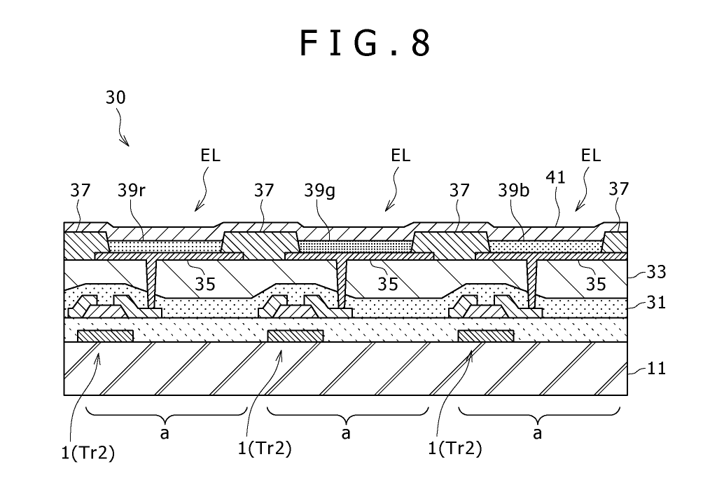

FIG. 8 is a diagram of a constitution of three pixels of a display device 30 to which the present technology is applied. The display device 30 is formed by using a thin film transistor according to an embodiment of the present technology as illustrated in one of the first to third embodiments. A constitution including the semiconductor device 1 described in the first embodiment, that is, a thin film transistor of a bottom gate and top contact structure will be shown in the following as an example.

As shown in FIG. 8, the display device 30 is an active matrix type display device 30 in which a pixel circuit using a thin film transistor 1 and an organic electroluminescent element EL connected to the pixel circuit are arranged in each pixel a on a substrate 11.

The top of the substrate 11 on which the pixel circuits using the thin film transistors 1 are arranged is covered with a passivation film 31, and a planarizing insulating film 33 is provided on the passivation film 31. A connecting hole 31a reaching each thin film transistor 1 is provided in the planarizing insulating film 33 and the passivation film 31. Pixel electrodes 35 connected to the thin film transistors via each connecting hole 31a are arranged and formed on the planarizing insulating film 33.

The periphery of each pixel electrode 35 is covered by a window insulating film 37 for device isolation. The surfaces of the respective device-isolated pixel electrodes 35 are covered by organic light emitting functional layers 39r, 39g, and 39b of respective colors, and a common electrode 41 common to each pixel a is further provided in a state of covering the organic light emitting functional layers 39r, 39g, and 39b. Each of the organic light emitting functional layers 39r, 39g, and 39b is of a laminated structure including at least an organic light emitting layer, at least the organic light emitting layer being pattern-formed with a constitution different on a pixel-by-pixel basis, and may have a layer common to each pixel. The common electrode 41 is formed as a cathode, for example, and suppose that the common electrode 41 is formed as a light transmitting electrode when the display device fabricated in this case is of a top emission type in which emitted light is extracted from an opposite side from the substrate 11.

Thus, organic electroluminescent elements EL are formed in the parts of the respective pixels a in which the organic light emitting functional layers 39r, 39g, and 39b are sandwiched between the pixel electrodes 35 and the common electrode 41. Incidentally, though not shown, a protective layer is further provided on the substrate 11 on which these organic electroluminescent elements EL are formed, and a sealing substrate is laminated via an adhesive to form the display device 30.

### <Circuit Configuration of Display Device>

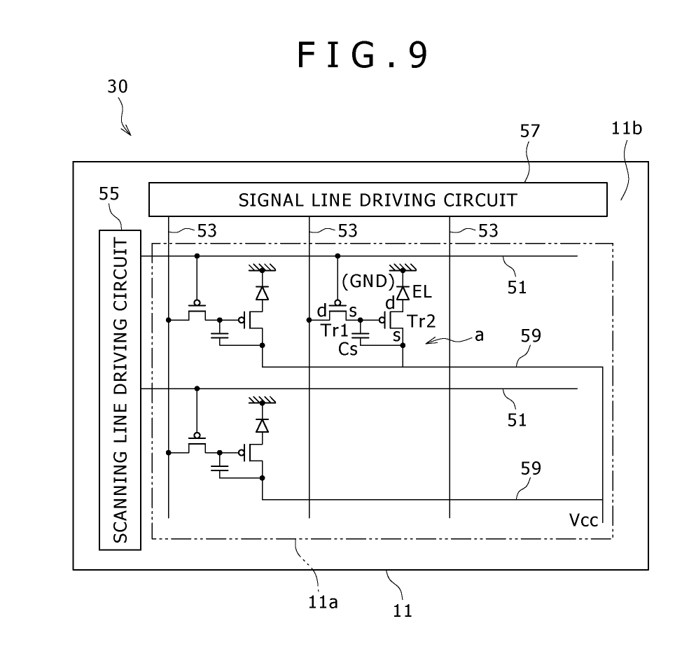

FIG. 9 is an example of a diagram of a circuit configuration of the display device 30. It is to be noted that the circuit configuration to be described in the following is a mere example.

As shown in FIG. 9, a display region 11a and a peripheral region 11b on the periphery of the display region 11a are set on the substrate 11 of the display device 30. The display region 11a is formed as a pixel array section in which a plurality of scanning lines 51 and a plurality of signal lines 53 are arranged vertically and horizontally and in which one pixel a is provided so as to correspond to each of the intersections of the plurality of scanning lines 51 and the plurality of signal lines 53. In addition, a scanning line driving circuit 55 for scanning and driving the scanning lines 51 and a signal line driving circuit 57 for supplying a video signal (that is, an input signal) corresponding to luminance information to the signal lines 53 are arranged in the peripheral region 11b.

A pixel circuit provided at each of the intersections of the scanning lines 51 and the signal lines 53 includes for example a thin film transistor Tr1 for switching, a thin film transistor Tr2 for driving, a storage capacitor Cs, and an organic electroluminescent element EL.

In the display device 30, a video signal written from a signal line 53 via the thin film transistor Tr1 for switching is retained in the storage capacitor Cs by the driving of the scanning line driving circuit 55. Then, a current corresponding to the retained signal quantity is supplied from the thin film transistor Tr2 for driving to the organic electroluminescent element EL, and the organic electroluminescent element EL emits light at a luminance corresponding to the value of the current. Incidentally, the thin film transistor Tr2 for driving is connected to a common power supply line (Vcc) 59.

It is to be noted that the configuration of the pixel circuit as described above is a mere example. A capacitance element may be provided within the pixel circuit as required, and a plurality of transistors may be further provided to form the pixel circuit. In addition, a necessary driving circuit is added to the peripheral region 11b according to a change in the pixel circuit.

In such a circuit configuration, the thin film transistors Tr1 and Tr2 are formed as a thin film transistor (semiconductor device) according to an embodiment of the present technology as illustrated in one of the foregoing embodiments. Incidentally, FIG. 8 shows a section of a part where the thin film transistor Tr2 and the organic electroluminescent element EL are laminated as a section of three pixels in the display device 30 of the circuit configuration as described above. The thin film transistor Tr1 for switching and the storage capacitor Cs are formed in the same layer as the thin film transistor Tr2 for driving. In addition, FIG. 9 illustrates a case where the thin film transistors Tr1 and Tr2 are of a p-channel type.

In the display device 30 of the configuration as described above, pixel circuits are formed using thin film transistors (semiconductor devices) improved in functionality, as described in the first to third embodiments. It is thereby possible to achieve a higher degree of integration and higher functionality of pixels.

Incidentally, in the present fourth embodiment described above, an organic EL display device has been shown as an example of a display device according to an embodiment of the present technology. However, a display device according to an embodiment of the present technology is widely applicable to display devices using a thin film transistor, particularly active matrix type display devices in which a thin film transistor is connected to a pixel electrode, and similar effects can be obtained. Examples of such a display device include a liquid crystal display device and an electrophoretic display device, and similar effects can be obtained.

### 5. Fifth Embodiment

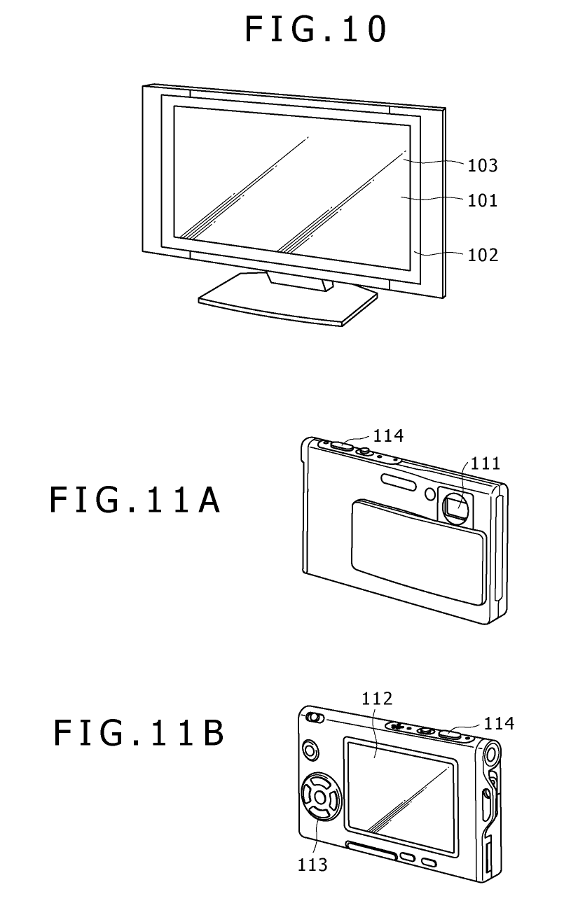

An example of electronic devices according to an embodiment of the present technology described above will be described with reference to FIGS. 10 to 14G. Suppose that the electronic devices to be described in the following are for example electronic devices using the display device described in the fourth embodiment as a display section. Incidentally, a display device according to an embodiment of the present technology, an example of which has been described in the fourth embodiment, is applicable to display sections in electronic devices in all fields, which display sections display video signals input to the electronic devices as well as video signals generated in the electronic devices. An example of electronic devices to which the present technology is applied will be described in the following.

FIG. 10 is a perspective view of a television set to which the present technology is applied. The television set according to the present example of application includes a video display screen part 101 composed of a front panel 102, a filter glass 103 and the like, and is fabricated using a display device according to an embodiment of the present technology as the video display screen part 101.

FIGS. 11A and 11B are perspective views of a digital camera to which the present technology is applied. FIG. 11A is a perspective view of the digital camera as viewed from a front side, and FIG. 11B is a perspective view of the digital camera as viewed from a back side. The digital camera according to the present example of application includes a light emitting part 111 for flashlight, a display part 112, a menu switch 113, a shutter button 114, and the like. The digital camera is fabricated using a display device according to an embodiment of the present technology as the display part 112.

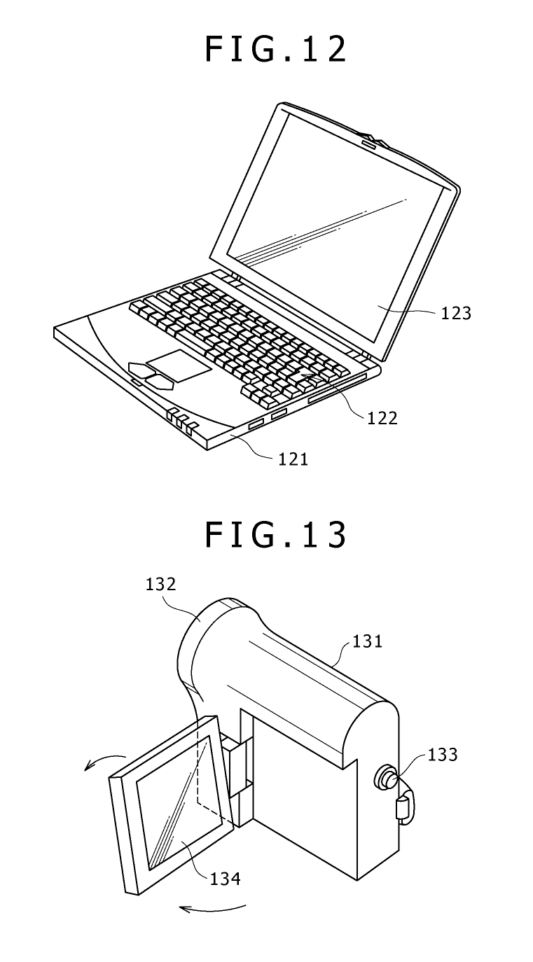

FIG. 12 is a perspective view of a notebook personal computer to which the present technology is applied. The notebook personal computer according to the present example of application includes a keyboard 122 operated to input characters and the like, a display part 123 for displaying an image, and the like in a main unit 121. The notebook personal computer is fabricated using a display device according to an embodiment of the present technology as the display part 123.

FIG. 13 is a perspective view of a video camera to which the present technology is applied. The video camera according to the present example of application includes a main unit 131, a lens 132 for taking a subject which lens is in a side surface facing frontward, a start/stop switch 133 at a time of picture taking, a display part 134, and the like. The video camera is fabricated using a display device according to an embodiment of the present technology as the display part 134.

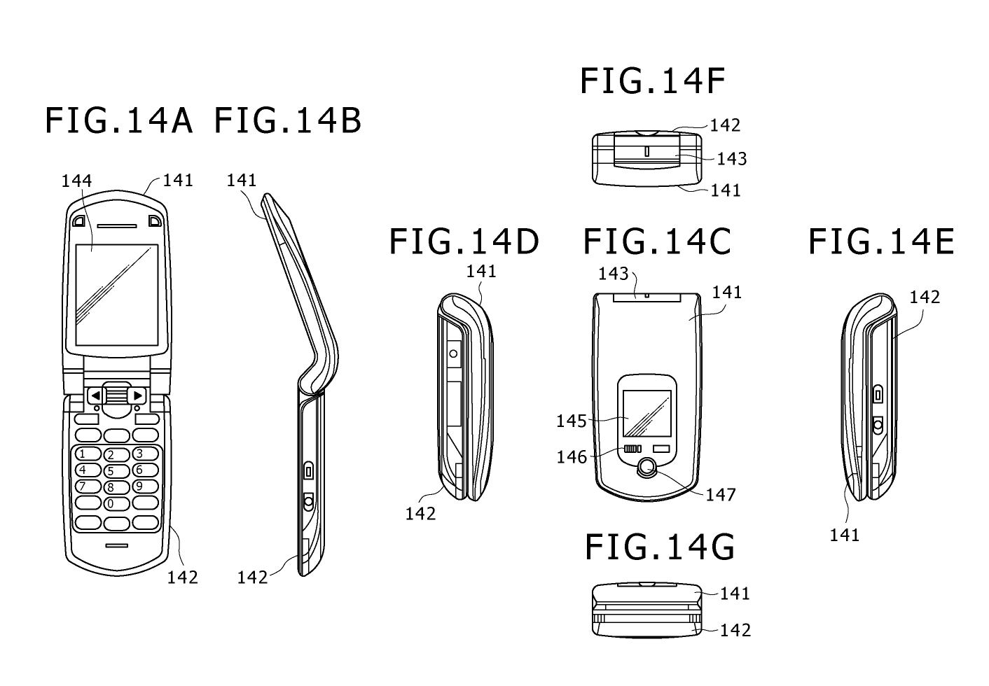

FIGS. 14A, 14B, 14C, 14D, 14E, 14F, and 14G are external views of a portable terminal device, for example a portable telephone to which the present technology is applied. FIG. 14A is a front view of the portable telephone in an opened state, FIG. 14B is a side view of the portable telephone in the opened state, FIG. 14C is a front view of the portable telephone in a closed state, FIG. 14D is a left side view of the portable telephone in the closed state, FIG. 14E is a right side view of the portable telephone in the closed state, FIG. 14F is a top view of the portable telephone in the closed state, and FIG. 14G is a bottom view of the portable telephone in the closed state. The portable telephone according to the present example of application includes an upper side casing 141, a lower side casing 142, a coupling part (a hinge part in this case) 143, a display 144, a sub-display 145, a picture light 146, a camera 147, and the like. The portable telephone according to the present example of application is fabricated using a display device according to an embodiment of the present technology as the display 144 and the sub-display 145.

Incidentally, the foregoing fifth embodiment illustrates respective examples of a display device and electronic devices using the display device as a display section as an example of electronic devices according to an embodiment of the present technology. However, electronic devices according to an embodiment of the present technology are not limited to application to objects using such a display section, but are widely applicable to electronic devices including a thin film transistor in a state of being connected to a conductive pattern. Electronic devices according to an embodiment of the present technology are applicable to electronic devices such as an ID tag, a sensor and the like as such an example, and similar effects can be obtained.

The present disclosure contains subject matter related to that disclosed in Japanese Priority Patent Application JP 2010-177799 filed in the Japan Patent Office on Aug. 6, 2010, the entire content of which is hereby incorporated by reference.

It should be understood by those skilled in the art that various modifications, combinations, sub-combinations and alternations may occur depending on design requirements and other factors insofar as they are within the scope of the appended claims or the equivalent thereof.

What is claimed is:

1. A semiconductor device comprising:
a gate electrode on a substrate;
a gate insulating film covering said gate electrode;
an organic semiconductor layer disposed so as to be superposed above said gate electrode with said gate insulating film interposed between the organic semiconductor layer and the gate electrode within a width of said gate electrode; and
a source electrode and a drain electrode having respective end parts disposed so as to be opposed to each other on said organic semiconductor layer in a state of said gate electrode being interposed between the source electrode and the drain electrode in a direction of the width of said gate electrode.

2. The semiconductor device according to claim 1, wherein film thickness of both edges of said organic semiconductor layer in the direction of width of said gate electrode is smaller than film thickness of a central part of said organic semiconductor layer in the direction of width of said gate electrode.

3. The semiconductor device according to claim 1, wherein a side wall of said organic semiconductor layer in the direction of width of said gate electrode is formed in a tapered shape.

4. The semiconductor device according to claim 1, wherein film thickness of both edges of said organic semiconductor layer in the direction of width of said gate electrode is reduced stepwise.

5. The semiconductor device according to claim 1, wherein a top surface of said organic semiconductor layer is covered by an insulating protective film with a side wall of said organic semiconductor layer exposed.

6. A display device comprising:
a thin film transistor; and
a pixel electrode connected to said thin film transistor,
said thin film transistor including
a gate electrode on a substrate,
a gate insulating film covering said gate electrode,
an organic semiconductor layer disposed so as to be superposed above said gate electrode with said gate insulating film interposed between the organic semiconductor layer and the gate electrode within a width of said gate electrode, and
a source electrode and a drain electrode having respective end parts disposed so as to be opposed to each other on said organic semiconductor layer in a state of said gate electrode being interposed between the source electrode and the drain electrode.

7. An electronic device comprising a thin film transistor, said thin film transistor including:
a gate electrode on a substrate;
a gate insulating film covering said gate electrode;
an organic semiconductor layer disposed so as to be superposed above said gate electrode with said gate insulating film interposed between the organic semiconductor layer and the gate electrode within a width of said gate electrode; and
a source electrode and a drain electrode having respective end parts disposed so as to be opposed to each other on said organic semiconductor layer in a state of said gate electrode being interposed between the source electrode and the drain electrode.
